(19) United States
(12) Patent Application Publication
(10) Pub. No.: US 2003/0059715 A1
(43) Pub. Date: Mar. 27, 2003

(54) Positive resist composition

(75) Inventor: Kenichiro Sato, Shizuoka (JP)

Correspondence Address: SUGHRUE MION, PLLC, 2100 PENNSYLVANIA AVENUE, N.W., WASHINGTON, DC, 20037, US

(73) Assignee: FUJI PHOTO FILM CO., LTD.

(21) Appl. No.: 10/146,896

(22) Filed: May 17, 2002

(30) Foreign Application Priority Data
May 18, 2001 (JP) P.2001-149862

(51) Int. Cl. G03F 7/039

(52) U.S. Cl. 430/287.1; 430/176; 430/270.1; 430/286.1; 430/192; 430/188; 430/945; 430/326

(57) ABSTRACT

A positive resist composition comprising the components of: (A) a resin having an aliphatic cyclic hydrocarbon group on its side chain and being capable of increasing the solubility in an alkali developer by an action of acid; and (B) a compound being capable of generating an acid by irradiation with one of an actinic light and radiation, wherein the component (A) is a resin comprising at least one of repeating unit having a partial structure comprising an alicyclic hydrocarbon represented by one of the following general formulae (pI) to (pVI), and the content of the repeating units corresponding to an acrylic monomer is from 5 to 45 mol % based on the total of the repeating units.

### FIELD OF THE INVENTION

The present invention relates to a positive resist composition used in an ultramicrolithography process or another photofabrication process for the production of an ULSI circuit or a high capacity microchip.

### BACKGROUND OF THE INVENTION

In recent years, integrated circuits have been progressively increased in their integration degree, and therefore processing of ultrafine patterns having a line width of a half micron or less has become necessary in the production of semiconductor substrates for ULSI circuits. For fulfilling this necessity, the wavelength of light used in exposure devices employed for photolithography has become progressively shorter, and now, of the far ultraviolet rays, the use of excimer laser light having a short wavelength (such as XeCl, KrF or ArF) has been studied.

Used in the pattern formation of lithography in this wavelength region are chemical amplification system resists.

In general, the chemical amplification system resists can be roughly divided into three classes, commonly called as 2-component system resists, 2.5-component system resists and 3-component system resists. In the 2-component system resist, a compound generating an acid by photolysis (hereinafter referred to as a photoacid generating agent) is combined with a binder resin. The binder resin is a resin having a group which is decomposable by the action of an acid to enhance the solubility of the resin in an alkali developing solution (also referred to as an acid-decomposable group) in its molecule. The 2.5-component system resin contains a low molecular weight compound further having an acid-decomposable group in addition to such a 2-component system resin. The 3-component system resin contains the photoacid generating agent, an alkali-soluble resin and the above-mentioned low molecular weight compound.

The above-mentioned chemical amplification system resists are suitable for photoresists for ultraviolet or far ultraviolet ray irradiation. However, they are further required to comply with desired characteristics for use.

As photoresist compositions for ArF light sources, there are proposed resins into which alicyclic hydrocarbon moieties are introduced for imparting the resistance to dry etching. However, the systems become extremely hydrophobic as an adverse effect of the introduction of the alicyclic hydrocarbon moieties. The phenomenon is therefore observed that the development with aqueous solutions of tetramethylammonium hydroxide (hereinafter referred to as TMAH) which have hitherto been widely used as resist developing solutions becomes difficult, or that resists are separated from substrates during the development.

For complying with such hydrophobization of resists, a measure of mixing organic solvents such as isopropyl alcohol with the developing solutions has been studied, and results have been observed although not quite satisfactorily. However, there is fear of swelling of resist films, and the process becomes complicated. It is therefore not necessarily said that problems have been solved. As approaches to the improvement of resists, there have been taken many measures for compensating for various hydrophobic alicyclic hydrocarbon moieties by the introduction of hydrophilic groups.

In Japanese Patent Laid-Open No. 73173/1997, resist materials are described in which acid-sensitive compounds containing alkali-soluble groups protected with alicyclic group-containing structures and structural units which are allowed to become alkali-soluble by eliminating the alkali-soluble groups with acids.

Proceedings of SPIE, Vol. 3999, pp. 974-979 (2000) describes that copolymer resins of adamantyl-based acrylic monomers having specific structures and lactone-based methacrylic monomers having specific structures are effective for the improvement of resist performance.

However, the conventional positive resist compositions have caused the problem of pattern falling, and have not sufficiently been improved in surface roughness in etching and defocusing latitude in microphotofabrication using far ultraviolet rays, particularly ArF excimer laser beams. The term “pattern falling” as used herein means that in forming a line pattern, the pattern falls down as if it breaks in the vicinity of a substrate interface.

### SUMMARY OF THE INVENTION

It is therefore an object of the invention to provide a positive resist composition which can be suitably used for microphotofabrication using far ultraviolet rays, particularly ArF excimer laser beams, prevents pattern falling, and is excellent in surface roughness in etching and defocusing latitude.

The present inventors have intensively studied materials constituting positive chemical amplification system resist compositions. As a result, the present inventors have discovered that the object of the invention is attained by using specific acid-decomposable resins and specific photoacid generating agents, thus completing the invention.

That is to say, the above-mentioned object is attained by the following constitution:

(1) A positive resist composition containing (A) a resin having an aliphatic cyclic hydrocarbon group on its side chain and enhanced in the rate of dissolution in an alkaline developing solution by an action of an acid, and (B) a compound generating an acid by irradiation of active light (actinic light) or radiation, wherein the resin of (A) is a resin having at least one kind of repeating unit having a partial structure containing an alicyclic hydrocarbon represented by any one of the following general formulas (pI) to (pVI), and the content of repeating units corresponding to (belonging to) an acrylic monomer is from 5 to 45 mol % based on the total repeating units:

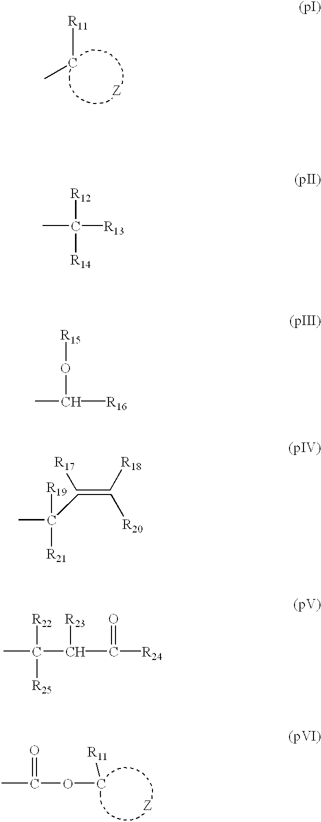

wherein R₁₁ represents a methyl group, an ethyl group, an n-propyl group, an isopropyl group, an n-butyl group, an isobutyl group or a sec-butyl group, and Z represents an atomic group necessary for forming an alicyclic hydrocarbon group together with a carbon atom; R₁₂ to R₁₆ each independently represents a straight-chain or branched alkyl group having from 1 to 4 carbon atoms or an alicyclic hydrocarbon group, with the proviso that at least one of R₁₂ to R₁₄, or either of R₁₅ and R₁₆ represents an alicyclic hydrocarbon group; R₁₇ to R₂₁ each independently represents a hydrogen atom, a straight-chain or branched alkyl group having from 1 to 4 carbon atoms or an alicyclic hydrocarbon group, with the proviso that at least one of R₁₇ to R₂₁, represents an alicyclic hydrocarbon group, and either of R₁₉ and R₂₁ represents a straight-chain or branched alkyl group having from 1 to 4 carbon atoms or an alicyclic hydrocarbon group; and R₂₂ to R₂₅ each independently represents a straight-chain or branched alkyl group having from 1 to 4 carbon atoms or an alicyclic hydrocarbon group, with the proviso that at least one of R₂₂ to R₂₅ represents an alicyclic hydrocarbon group, and R₂₃ and R₂₄ may combine with each other to form a ring;

(2) The positive resist composition described in the above (1), wherein the content of the repeating units corresponding to the acrylic monomer in the resin of (A) is from 10 to 40 mol % based on the total repeating units;

(3) The positive resist composition described in the above (1), wherein the content of the repeating units corresponding to the acrylic monomer in the resin of (A) is from 15 to 35 mol % based on the total repeating units;

(4) The positive resist composition described in any one of the above (1) to (3), which further contains (C) a fluorine and/or silicone surfactant; and

(5) The positive resist composition described in any one of the above (1) to (4), which further contains (D) an organic basic compound.

### DETAILED DESCRIPTION OF THE INVENTION

Components used in the invention will be described in detail below.

[1] (A) Resin Enhanced in the Rate of Dissolution in Alkaline Developing Solution by Action of Acid (hereinafter also referred to as “Acid-Decomposable Resin”)

As the acid-decomposable resin (A) of the invention, there is used a resin having an aliphatic cyclic hydrocarbon group on a side chain and enhanced in the rate of dissolution in an alkaline developing solution by an action of an acid, and having at least one kind of repeating unit having a partial structure containing an alicyclic hydrocarbon represented by any one of the above-mentioned general formulas (pI) to (pVI)

In general formulas (pI) to (pVI), the alkyl group represented by R₁₂ to R₂₅ is a straight-chain or branched alkyl group having from 1 to 4 carbon atoms, which may be either substituted or unsubstituted. Examples of the alkyl groups include methyl, ethyl, n-propyl, isopropyl, n-butyl, isobutyl, sec-butyl and t-butyl.

Further substituent groups of the alkyl groups include an alkoxyl group having from 1 to 4 carbon atoms, a halogen atom (fluorine, chlorine, bromine or iodine), an acyl group, an acyloxy group, a cyano group, a hydroxyl group, a carboxyl group, an alkoxycarbonyl group and a nitro group.

The alicyclic hydrocarbon group represented by R₁₂ to R₂₅ or the alicyclic hydrocarbon group formed by Z and a carbon atom may be either monocyclic or polycyclic. Specific examples thereof include groups having monocyclo, bicyclo, tricyclo and tetracyclo structures, each of which has 5 or more carbon atoms, preferably from 6 to 30 carbon atoms and particularly preferably from 7 to 25 carbon atoms. These alicyclic hydrocarbon groups may have substituent groups.

Of the alicyclic hydrocarbon groups, structural examples of alicyclic moieties are shown below:

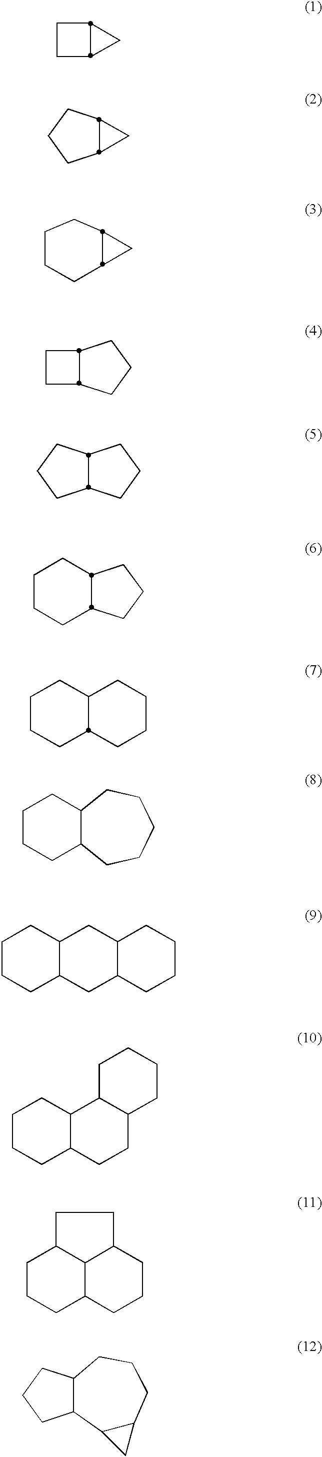

In the invention, preferred examples of the alicyclic moieties include adamantyl, noradamantyl, decalin residue, tricyclodecanyl, tetracyclododecanyl, norbornyl, cedrol, cyclohexyl, cycloheptyl, cyclooctyl, cyclodecanyl and cyclododecanyl, and more preferred are adamantyl, decalin residue, norbornyl, cedrol, cyclohexyl, cycloheptyl, cyclooctyl, cyclodecanyl and cyclododecanyl.

Substituent groups of these alicyclic hydrocarbon groups include an alkyl group, a substituted alkyl group, a halogen atom, a hydroxyl group, an alkoxyl group, a carboxyl group and an alkoxycarbonyl group. The alkyl groupispreferablyalower alkyl group such as methyl, ethyl, propyl, isopropyl or butyl, and more preferably represents a substituent group selected from the group consisting of methyl, ethyl, propyl and isopropyl. Substituent groups of the substituted alkyl groups include a hydroxyl group, a halogen atom and alkoxyl group. The alkoxyl groups include an alkoxyl group having from 1 to 4 carbon atoms such as methoxy, ethoxy, propoxy or butoxy.

The structures represented by general formulas (pI) to pVI) in the above-mentioned resins can be used for the protection of alkali-soluble groups. The alkali-soluble groups include various groups known in this technical field.

Specific examples thereof include a carboxylic acid group, a sulfonic acid group, a phenol group and a thiol group, and preferred are a carboxylic acid group and a sulfonic acid group.

The alkali-soluble groups protected with the structures represented by general formulas (pI) to pVI) in the above-mentioned resins preferably include groups represented by the following general formulas (pVII) to (pXI):

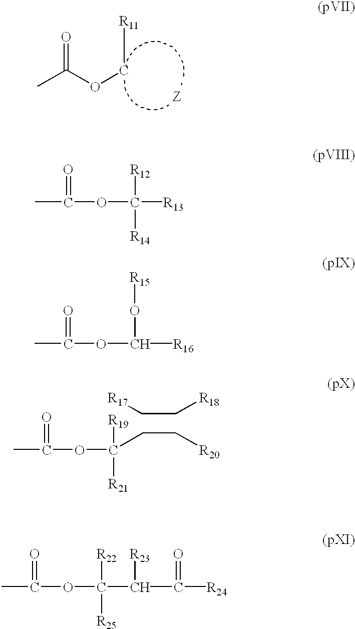

wherein R₁₁ to R₂₅ and Z have the same meanings as given above, respectively.

The repeating units having the alkali-soluble groups protected with the structures represented by general formulas (pI) to pVI) in the above-mentioned resins are preferably repeating units represented by the following general formula (pA):

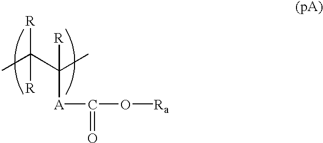

wherein R represents a hydrogen atom, a halogen atom or an unsubstituted or substituted, straight-chain or branched alkyl group having 1 to 4 carbon atoms, and a plurality of R's may be the same or different; A represents a single bond (single group) or a combination of two or more groups selected from the group consisting of a single bond, an alkylene group, a substituted alkylene group, an ether group, a thioether group, a carbonyl group, an ester group, an amido group, a sulfonamido group, a urethane group and a urea group; and Ra represents any one of the groups represented by the above-mentioned formulas (pI) to (pVI).

Specific examples of monomers corresponding to the repeating units represented by general formula (pA) are shown below:

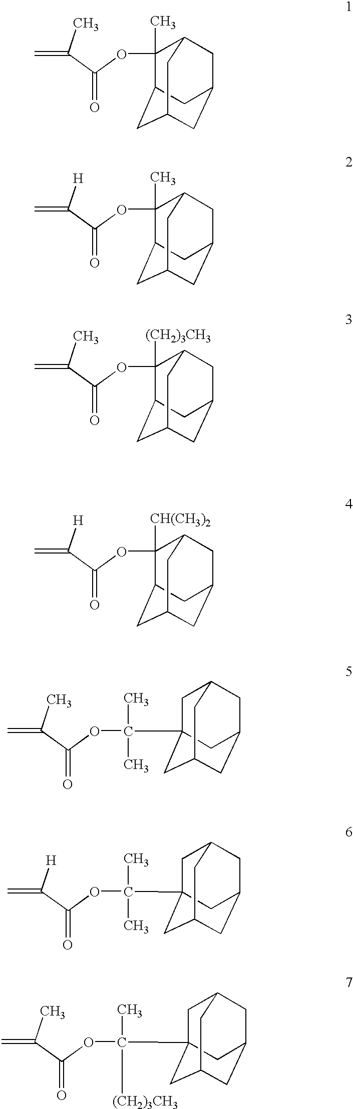

In the resin used in the invention, the structure of the acid-decomposable group is represented by—(=O)—X_{1═}—R₀, wherein R₀ represents a tertiary alkyl group such as t-butyl or t-amyl, a 1-alkoxyethyl group such as isobornyl, 1-ethoxyethyl, 1-butoxyethyl, 1-isobutoxyethyl or 1-cyclohexyloxyethyl, an alkoxymethyl group such as 1-methoxymethyl or 1-ethoxymethyl, 3-oxoalkyl group, a tetrahydropyranyl group, a tetra-hydrofuranyl group, a trialkylsilyl ester group, a 3-oxo-cyclohexyl ester group, a 2-methyl-2-adamantyl group or a mevalonic lactone residue; and X₁ represents an oxygen atom, a sulfur atom, —NH—, —NHSO₂— or —NHSO₂NH—.

In the resin used in the invention, more preferred is an acid-decomposable group indicated by the following general formula (a), and particularly preferred is an acid—decomposable group indicated by the following general formula (b):

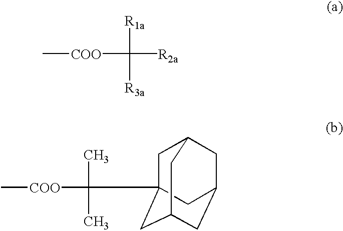

In the above-mentioned structure, R₁ₐ to R₃ₐ each independently represents an alkyl group such as methyl, ethyl, propyl, butyl, cyclohexyl or adamantyl.

Monomers having such acid-decomposable groups include, for example, 5, 6, 7, 8, 9, 10, 27, 28 and 29 mentioned above as the monomers corresponding to the repeating units indicated by general formula (pA).

In the resin used in the invention, the acid-decomposable group can be contained in at least one of the repeating units having the partial structures containing the alicyclic hydrocarbons indicated by the above-mentioned general formulas (pI) to (pVI) and repeating units of copolymerizable components described later.

The acid-decomposable resin of the invention can further contain repeating units having a lactone structure represented by the following general formula (IV):

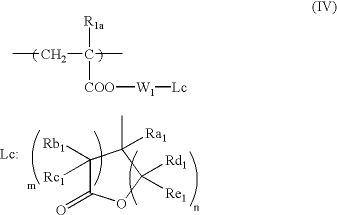

In general formula (IV), R₁ₐ represents a hydrogen atom or a methyl group.

W₁ represents a single bond (single group) or a combination of two or more groups selected from the group consisting of a single bond, an alkylene group, an ether group, a thioether group, a carbonyl group and an ester group.

Ra₁, Rb₁, Rc₁, Rd₁ and Re₁ each independently represents a hydrogen atom or an alkyl group having from 1 to 4 carbon atoms. m and n each independently represents an integer of from 0 to 3, and m+n is from 2 to 6.

The alkyl groups of 1 to 4 carbon atoms represented by Ra₁ to Re₁, include methyl, ethyl, propyl, isopropyl, n-butyl, isobutyl, sec-butyl and t-butyl.

In general formula (IV), the alkylene groups represented by W₁ include a group represented by the following formula:

—┌C(Rf)(Rg)┐r₁—

wherein Rf and Rg, which may be the same or different, each represents a hydrogen atom, an alkyl group, a substituted alkyl group, a halogen atom, a hydroxyl group or an alkoxyl group. The alkyl group is preferably a lower alkyl group such as methyl, ethyl, propyl, isopropyl or butyl, and more preferably, it is selected from methyl, ethyl, propyl and isopropyl. Substituent groups of the substituted alkyl groups include a hydroxyl group, a halogen atom and an alkoxyl group. The alkoxyl groups include an alkoxyl group having from 1 to 4 carbon atoms such as methoxy, ethoxy, propoxy or butoxy. The halogen atoms include chlorine, bromine, fluorine and iodine. r₁ is an integer of from 1 to 10.

Further substituent groups of the above-mentioned alkyl groups include a carboxyl group, an acyloxy group, a cyano group, an alkyl group, a substituted alkyl group, a halogen atom, a hydroxyl group, an alkoxyl group, a substituted alkoxyl group, acetylamido group, an alkoxycarbonyl group and an acyl group.

The alkyl groups used herein include a lower alkyl group such as methyl, ethyl, propyl, isopropyl, butyl, cyclopropyl, cyclobutyl or cyclopentyl. Substituent groups of the substituted alkyl groups include a hydroxyl group, a halogen atom and an alkoxyl group. Substituent groups of the substituted alkoxyl groups include an alkoxyl group. The alkoxyl groups include an alkoxyl group having from 1 to 4 carbon atoms such as methoxy, ethoxy, propoxy or butoxy. The ark acyloxy groups include an acetoxy group. The halogen atoms include chlorine, bromine, fluorine and iodine.

Specific examples of the repeating structural units indicated by general formula (IV) are shown below, but are not limited thereto:

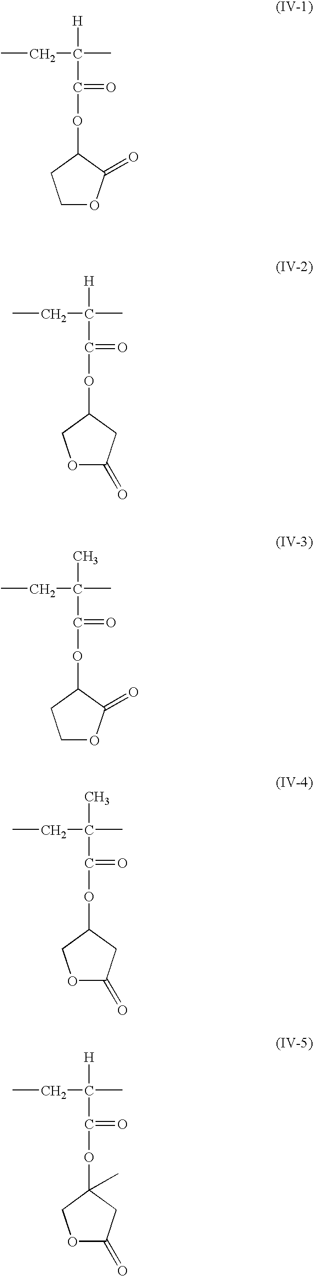

Of the above-mentioned specific examples of general formula (IV), (IV-17) to (IV-36) are preferred in that the exposure margin is more improved.

Further, the structure of general formula (IV) is preferably one having an acrylate structure in that edge roughness is improved.

Still further, repeating units having a group represented b any one of the following general formulas (V-1) to (V-4) may be contained:

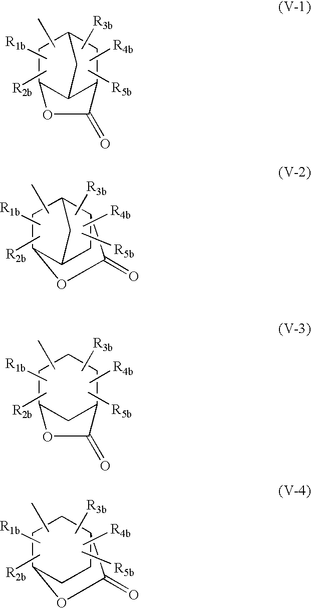

In general formulas (V-1) to (V-4), R_{1b} to R_{5b} each independently represents a hydrogen atom or an alkyl, cycloalkyl or alkenyl group which may have a substituent group. Two of R_{1b} to R_{5b} may combine with each other to form a ring.

In general formulas (V-1) to (V-4), the alkyl groups represented by R_{1b} to R_{5b} include a straight-chain or branched alkyl group, which may have a substituent group. The straight-chain or branched alkyl group is preferably a straight-chain or branched alkyl group having from 1 to 12 carbon atoms, more preferably a straight-chain or branched alkyl group having from 1 to 10 carbon atoms, and still more preferably methyl, ethyl, propyl, isopropyl, n-butyl, isobutyl, sec-butyl, t-butyl, pentyl, hexyl, heptyl, octyl, nonyl or decyl.

The cycloalkyl groups represented by R_{1b} to R_{5b} are preferably an alkenyl group having from 3 to 8 carbon atoms such as cyclopropyl, cyclopentyl, cyclohexyl, cycloheptyl or cyclooctyl.

The alkenyl groups represented by R_{1b} to R_{5b} are preferably an alkenyl group having from 2 to 6 carbon atoms such as vinyl, propenyl, butenyl or hexenyl.

Further, the rings formed by combining two of R_{1b} to R_{5b} with each other include 3- to 8-membered rings such as a cyclopropane ring, a cyclobutane ring, a cyclopentane ring, a cyclohexane ring and cyclooctane ring.

R_{1b} to R_{5b} in general formulas (V-1) to (V-4) may each combine with any carbon atom constituting a cyclic skeleton.

Preferred examples of the substituent groups which may be contained in the above-mentioned alkyl, cycloalkyl and alkenyl groups include an alkoxyl group having from 1 to 4 carbon atoms, a halogen atom (fluorine, chlorine, bromine or iodine), an acyl group having from 2 to 5 carbon atoms, an acyloxy group having from 2 to 5 carbon atoms, a cyano group, a hydroxyl group, a carboxyl group, an alkoxycarbonyl group having from 2 to 5 carbon atoms and a nitro group.

The repeating units having the groups represented by general formulas (V-1) to (V-4) include repeating units represented by the following general formula (AI):

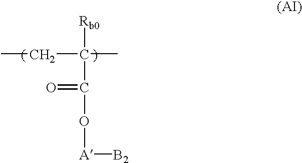

In general formula (AI), R_{b0} represents a hydrogen atom, a halogen atom or an unsubstituted or substituted alkyl group having from 1 to 4 carbon atomrs. Preferred examples of the substituent groups which may be contained in the alkyl groups represented by R_{b0} include thesubstituent groups exemplified above as the preferred ones which may be contained in the alkyl groups represented by R_{1b} in the above-mentioned general formulas (V-1) to (V-4)

The halogen atoms represented by R_{b0} include fluorine, chlorine, bromine and iodine. R_{b0} is preferably hydrogen.

A′ represents a single bond, an ether group, an ester group, a carbonyl group, an alkylene group or a divalent group which is a combination thereof.

B₂ represents a group indicated by any one of general formulas (V-1) to (V-4). In A′, the combined divalent groups include, for example, groups represented by the following formulas:

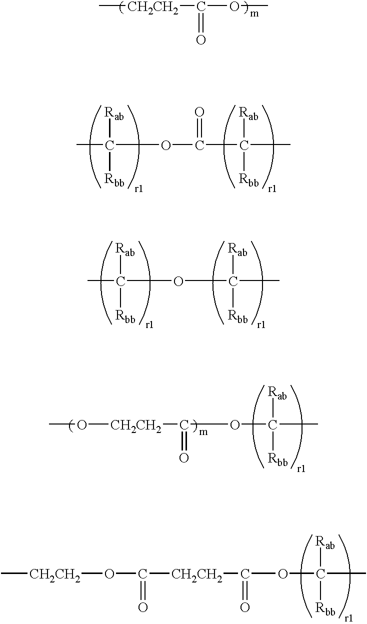

In the above-mentioned formulas, R_{ab} and R_{bb}, which may be the same or different, each represents a hydrogen atom, an alkyl group, a substituted alkyl group, a halogen atom, a hydroxyl group or an alkoxyl group.

The alkyl group is preferably a lower alkyl group such as methyl, ethyl, propyl, isopropyl or butyl, and more preferably, it is selected from methyl, ethyl, propyl and isopropyl. Substituent groups of the substituted alkyl groups include a hydroxyl group, a halogen atom and an alkoxyl group having from 1 to 4 carbon atoms.

The alkoxyl groups include an alkoxyl group having from 1 to 4 carbon atoms such as methoxy, ethoxy, propoxy or butoxy. The halogen atoms include chlorine, bromine, fluorine and iodine. r1 represents an integer of from 1 to 10, and preferably an integer of from 1 to 4. m represents an integer of from 1 to 3, and preferably 1 or 2.

Specific examples of the repeating units represented by general formula (AI′) are enumerated below, but the scope of the invention is not limited thereto:

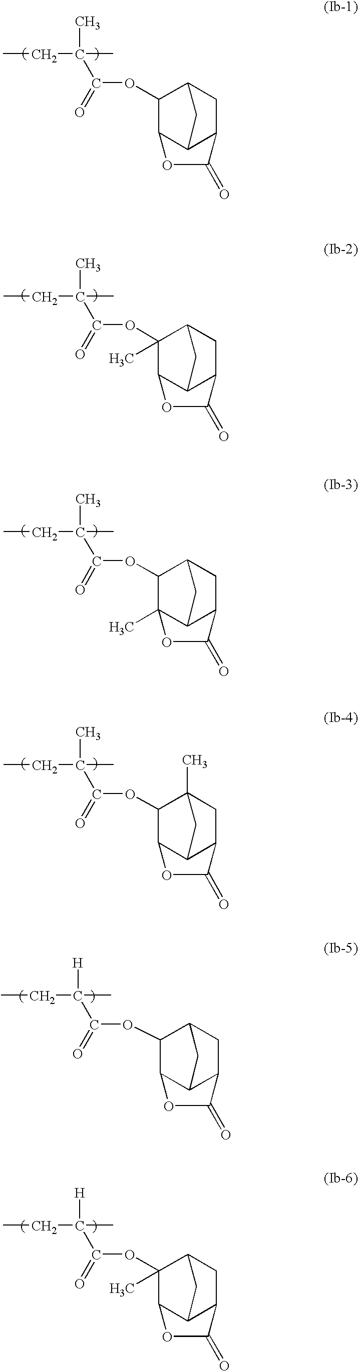

The acid-decomposable resins used in the invention can further contain repeating units represented by the following general formula (VI):

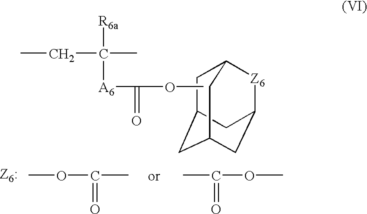

In general formula (VI), A₆ represents a single bond or a combination of two or more groups selected from the group consisting of a single bond, an alkylene group, a cycloalkylene group, an ether group, a thioether group, a carbonyl group and an ester group.

R₆ₐ represents a hydrogen atom, an alkyl group having from 1 to 4 carbon atoms, a cyano group or a halogen atom.

In general formula (VI), the alkylene groups represented by A₆ include a group represented by the following formula:

—[C(Rnf)(Rng)]r—

wherein Rnf and Rng, which may be the same or different, each represents a hydrogen atom, an alkyl group, a substituted alkyl group, a halogen atom, a hydroxyl group or an alkoxyl group. The alkyl group is preferably a lower alkyl group such as methyl, ethyl, propyl, isopropyl or butyl, and more preferably, it is selected from methyl, ethyl, propyl and isopropyl. Substituent groups of the substituted alkyl groups include a hydroxyl group, a halogen atom and an alkoxyl group. The alkoxyl groups include an alkoxyl group having from 1 to 4 carbon atoms such as methoxy, ethoxy, propoxy or butoxy. The halogen atoms include chlorine, bromine, fluorine and iodine. r is an integer of from 1 to 10.

In general formula (VI), the cycloalkylene groups represented by A₆ include a cycloalkylene group having from 3 to 10 carbon atoms such as cyclopentylene, cyclohexylene or cyclooctylene.

The alicyclic ring containing Z₆ may have a substituent group. The substituent groups include, for example, a halogen atom, an alkoxyl group (preferably having from 1 to 4 carbon atoms), an alkoxycarbonyl group (preferably from 1 to 5 carbon atoms), an acyl group (for example, formyl or benzoyl), an acyloxy group (for example, propylcarbonyloxy or benzoyloxy), an alkyl group (preferably having from 1 to 4 carbon atoms), a carboxyl group, a hydroxyl group and an alkylsulfonylsulfamoyl group (such as —CONHSO₂CH₃). The alkyl group as the substituent group may further be substituted by ahydroxyl group, a halogen atom or analkoxyl group (preferably having from 1 to 4 carbon atoms).

In general formula (VI), the oxygen atom of the ester group bound to A₆ may combine with a carbon atom constituting the alicyclic ring structure containing Z₆ at any position.

Specific examples of the repeating units represented by general formula (VI) are enumerated below, but are not limited thereto:

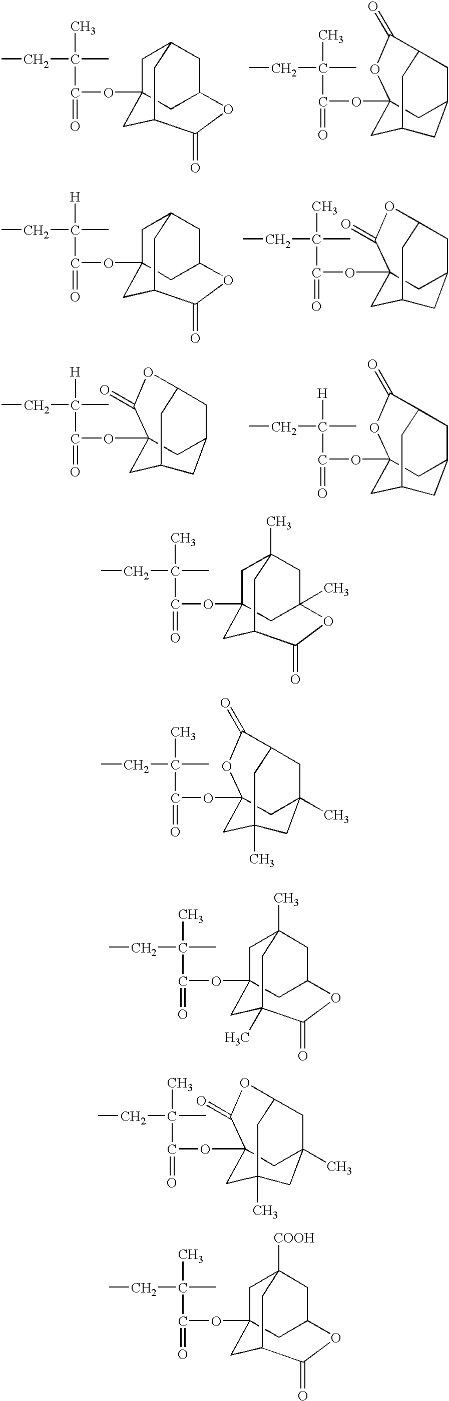

Further, repeating units having a group represented by the following general formula (VII) may be contained.

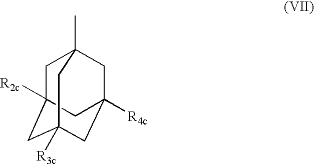

In general formula (VII), R_{2c}. to R_{4c}. each independently represents a hydrogen atom or a hydroxyl group, with the proviso that at least one of R_{2c}, to R_{4c}, represents a hydroxyl group.

The group represented by general formula (VII) is preferably a dihydroxyl form or a monohydroxyl form, and more preferably a dihydroxyl form.

The repeating units having the group represented by general formula (VII) include repeating units represented by the following general formula (AII):

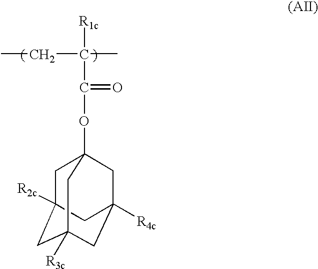

In general formula (AII) R_{1c} represents a hydrogen atom or a methyl group.

R_{2c} to R_{4c}. each independently represents a hydrogen atom or a hydroxyl group, with the proviso that at least one of R_{2c} to R_{4c} represents a hydroxyl group.

Specific examples of the repeating units having the structure represented by general formula (AII) are enumerated below, but are not limited thereto:

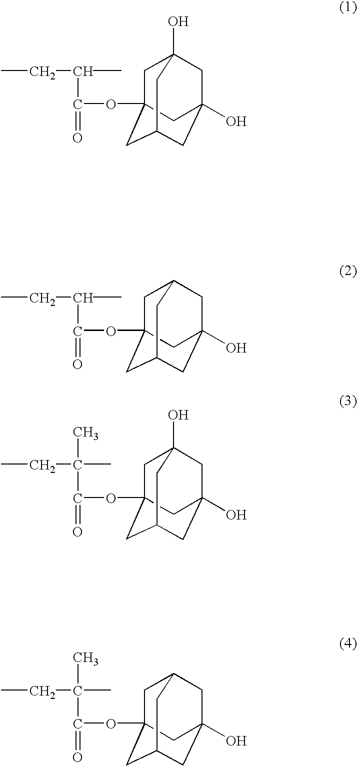

The acid-decomposable resin, component (A), can contain various repeating structural units, in addition to the above-mentioned repeating structural units, for controlling dry etching resistance, standard developing solution suitability, substrate adhesion, resist profiles, and further resolving power, heat resistance and sensitivity which are characteristics generally necessary for resists.

Such repeating structural units include but are not limited to repeating structural units corresponding to the following monomers. This makes it possible to perform fine adjustments of performances required for the acid decomposable reins, particularly,

(1) Solubility in coating solvents;

(2) Film forming properties (glass transition point);

(3) Alkali developing properties;

(4) Film decrease (hydrophilicity and hydrophobicity, and selection of alkali-soluble groups);

(5) Adhesion of unexposed areas to substrates; and

(6) Dry etching resistance.

Such monomers include, for example, a compound having one addition-polymerizable unsaturated bond selected from an acrylic acid ester, a methacrylic acid ester, an acrylamide, a methacrylamide, an allyl compound, a vinyl ether and a vinyl ester.

Specific examples thereof include the following monomers:

Acrylic acid esters (preferably alkyl acrylates wherein the alkyl groups each has from 1 to 10 carbon atoms):

Methyl acrylate, ethyl acrylate, propyl acrylate, amyl acrylate, cyclohexyl acrylate, ethylhexyl acrylate, octyl acrylate, t-octyl acrylate, chloroethyl acrylate, 2-hydroxy ethyl acrylate, 2,2-dimethylhydroxypropyl acrylate, 5-hydroxypentyl acrylate, trimethylolpropane monoacrylate, pentaerythritol monoacrylate, benzyl acrylate, methoxybenzyl acrylate, furfuryl acrylate and tetrahydrofurfuryl acrylate.

Methacrylic acid esters (preferably alkyl methacrylates wherein the alkyl groups each has from 1 to 10 carbon atoms):

Methyl methacrylate, ethyl methacrylate, propyl methacrylate, isopropyl methacrylate, amyl methacrylate, hexyl methacrylate, cyclohexyl methacrylate, benzyl meth-acrylate, chlorobenzyl methacrylate, octyl methacrylate, 2-hydroxyethyl methacrylate, 4-hydroxybutyl methacrylate, 5-hydroxypentyl methacrylate, 2,2-dimethyl-3-hydroxypropyl methacrylate, trimethylolpropane monomethacrylate, pentaerythritol monomethacrylate, furfuryl methacrylate and tetrahydrofurfuryl methacrylate.

Acrylamides

Acrylamide, N-alkylacrylamides (the alkyl groups each has from 1 to 10 carbon atoms, for example, methyl, ethyl, propyl, butyl, t-butyl, heptyl, octyl, cyclohexyl and hydroxyethyl), N,N-dialkylacrylamides (the alkyl groups each has from 1 to 10 carbon atoms, for example, methyl, ethyl, butyl, isobutyl, ethylhexyl and cyclohexyl), N-hydroxyethyl-N-methylacrylamide and N-2-acetamidoethyl-N-acetylacrylamide.

Methacrylamides

Methacrylamide, N-alkylmethacrylamides (the alkyl groups each has from 1 to 10 carbon atoms, for example, methyl, ethyl, t-butyl, ethylhexyl, hydroxyethyl and cyclohexyl), N,N-dialkylmethacrylamides (the alkyl groups include ethyl, propyl and butyl) and N-hydroxyethyl-N-methylacrylamide.

Allyl Compounds

Allyl esters (for example, allyl acetate, allyl caproate, allyl caprylate, allyl laurate, allyl palmitate, allyl stearate, allyl benzoate, allyl acetoacetate and allyl lactate) and allyloxyethanol.

Vinyl Ethers

Alkyl vinyl ethers (for example, hexyl vinyl ether, octyl vinyl ether, decyl vinyl ether, ethylhexyl vinyl ether, methoxyethyl vinyl ether, ethoxyethyl vinyl ether, chloroethyl vinyl ether, 1-methyl-2,2-dimethylpropyl vinyl ether, 2-ethylbutyl vinyl ether, hydroxyethyl vinyl ether, diethylene glycol vinyl ether, dimethylaminoethyl vinyl ether, diethylaminoethyl vinyl ether, butylaminoethyl vinyl ether, benzyl vinyl ether and tetrahydrofurfuryl vinyl ether).

Vinyl eaters

Vinyl butyrate, vinyl isobutyrate, vinyl trimethylacetate, vinyl diethylacetate, vinyl valerate, vinyl caproate, vinyl chloroacetate, vinyl dichloroacetate, vinyl methoxyacetate, vinyl butoxyacetate, vinyl acetoacetate, vinyl lactate, vinyl-β-phenyl butyrate and vinyl cyclohexylcarboxylate.

Dialkyl itaconate

Dimethyl itaconate, diethyl itaconate and dibutyl itaconate.

Dialkyl or monoalkyl esters of fumaric acid; dibutyl fumarate.

Others

Crotonic acid, itaconic acid, maleic anhydride, maleimide, acrylonitrile, methacrylonitrile and maleylonitrile.

Besides, addition-polymerizable unsaturated compounds may be copolymerized, as long as they are copolymerizable with monomers corresponding to the above-mentioned various repeating structural units.

The molar ratio of the respective repeating structural units contained in the acid-decomposable resin is appropriately established for controlling dry etching resistance, standard developing solution suitability, substrate adhesion, resist profiles, and further resolving power, heat resistance and sensitivity which are characteristics generally necessary for resists.

In the acid-decomposable resin, the content of the repeating units having the partial structures containing the alicyclic hydrocarbons represented by general formulas (pI) to (pVI) is preferably from 30 to 70 mol %, more preferably from 35 to 65 mol %, and still more preferably from 40 to 60 mol %, based on the total repeating structural units.

The total content of the repeating units represented by general formulas (IV) to (VII) is preferably from 5 to 70 mol %, more preferably from 10 to 65 mol %, and still more preferably from 15 to 60 mol %, based on the total repeating structural units.

The content of the repeating units having the acid-decomposable groups containing the repeating units having the partial structures containing the alicyclic hydrocarbons represented by general formulas (pI) to (pVI) is preferably from 30 to 70 mol %, more preferably from 35 to 65 mol %, and still more preferably from 40 to 60 mol %, based on the total repeating structural units.

In the acid-decomposable resin used in the invention, the content of the repeating units corresponding to the acrylic monomer is from 5 to 45 mol %, preferably from 10 to 40 mol %, and more preferably from 15 to 35 mol %, based on the total repeating units. When the content of the repeating units corresponding to the acrylic monomer is either more than 45 mol % or less than 5 mol %, resolving properties are unfavorably deteriorated.

The acid-decomposable resins used in the invention can be synthesized by usual methods (for example, radical polymerization). For example, according to a general synthesis method, monomer species are placed in a reaction vessel collectively or during the reaction, and dissolved in a reaction solvent, for example, an ether such as tetrahydrofuran, 1,4-dioxane or diisopropyl ether, a ketone such as methyl ethyl ketone or methyl isobutyl ketone, an ester solvent such as ethyl acetate, or a solvent dissolving the composition of the invention such as propylene glycol monomethyl ether acetate described later, as needed, to homogenize them. Then, polymerization is initiated in an atmosphere of an inert gas such as nitrogen or argon by heating as needed and by using a commercially available radical initiator (such as an azo initiator or a peroxide). The initiator may be added additionally or in parts as desired. After the reaction is completed, the reaction product is poured into a solvent to recover a desired polymer by powder or solid recovery. The reaction concentration is 20% by weight or more, preferably 30% by weight or more, and more preferably 40% by weight or more. The reaction temperature is from 10° C. to 150° C., preferably from 30° C. to 120° C., and more preferably from 50° C. to 100° C.

The weight average molecular weight of the resin used in the invention ispreferably from 1,000 to 200,000, as a value measured by the GPC method and converted to that of polystyrene. When the weight average molecular weight is less than 1,000, deterioration of heat resistance or dry etching resistance is unfavorably observed. On the other hand, exceeding 200,000 unfavorably results in deterioration of developing properties or deterioration of film forming properties because of its extremely increased viscosity.

When the composition of the invention is used for ArF exposure, it is preferred that the resin has no aromatic ring from the viewpoint of transparency to ArF light.

It is preferred that the resin has no alicyclic group on its main chain, because the resin is excellent in passing ability of contact holes and significantly improved in defocusing latitude (the allowable range of defocusing)

In the positive photoresist composition for far ultraviolet exposure of the invention, the amount of all resins according to the invention compounded in the whole composition is preferably from 40% to 99.99% by weight, and more preferably from 50% to 99.97% by weight, based on the total resist solid content.

[2] (B) Compound Generating Acid by Irradiation of Active Light or Radiation (Photoacid Generating Agent)

The photoacid generating agent used in the invention is a compound generating an acid by irradiation of active light or radiation.

As the photoacid generating agents used in the invention, there can be appropriately selected for use photoinitiators for cationic photo-polymerization, photoinitiators for radical photo-polymerization, photodecolorizing agents and photodiscoloring agents for dyes, or compounds generating acids with known light used in microresists (ultraviolet rays of 400 to 200 nm, far ultraviolet rays, particularly preferably g-rays, h-rays, i-rays and KrF excimer laser beams), ArF excimer laser beams, electron beams, X-rays, molecular beams or ion beams, and mixtures thereof.

The other photoacid generating agents used in the invention include, for example, an onium ion such as a diazonium salt, an ammonium salt, a phosphonium salt, an iodonium salt, a sulfonium salt, a selenonium or an arsonium salt, an organic halogen compound, an organic metal/organic halide, an o-nitrobenzyl protective group-containing photoacid generating agent, a compound generating a sulfonic acid by photolysis represented by an iminosulfonate, a disulfone compound, a diazoketosulfone compound and a diazodisulfone compound.

Further, compounds can be used in which these groups or compounds generating acids with light are introduced into main chains or side chains of the polymers.

Furthermore, compounds generating acids with light can also be used which are described in V. N. R. Pillai, Synthesis, (1) 1 (1980), A. Abad et al., Tetrahedron Lett., (47), 4555 (1971), D. H. R. Barton et al., J. Chem. Soc., (C), 329 (1970), U.S. Pat. No. 3,779,778 and European Patent 126,712.

Of the above-mentioned compounds which are decomposable by irradiation of active light or radiation to generate acids, compounds particularly effectively used are described below.

(1) Oxazole derivatives substituted by trihalomethyl groups, which are represented by the following general formula (PAG1), or S-triazine derivatives representedby the following general formula (PGA2):

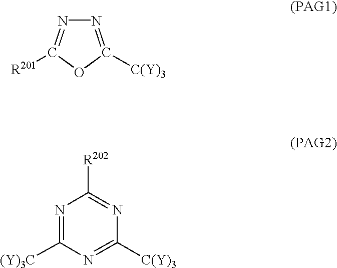

wherein R²⁰¹ represents an unsubstituted or substituted aryl or alkenyl group; R²⁰² represents an unsubstituted or substituted aryl, alkenyl or alkyl group, or —C(Y)₃; and Y represents a chlorine atom or a bromine atom.

Specific examples thereof include but are not limited to the following compounds:

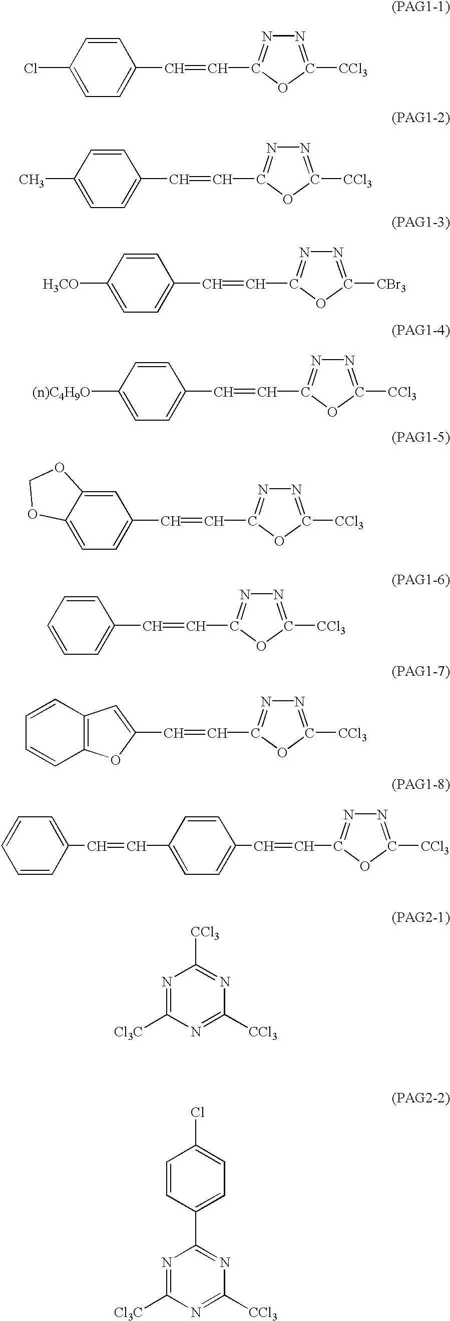

(2) Iodonium salts represented by the following general formula (PAG3) or sulfonium salts represented by the following general formula (PAG4):

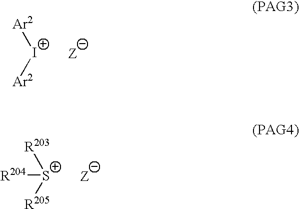

wherein Ar¹ and Ar² each independently represents an unsubstituted or substituted aryl group.

R²⁰³ ,R²⁰⁴ and R²⁰⁵ each independently represents an unsubstituted or substituted alkyl or aryl group.

Z⁻represents a counter ion, and examples thereof include but are not limited to BF₄⁻, AsF₆⁻, PF₆⁻, SbF₆ ⁻, SiF₆²⁻, C10₄⁻, a perfluoroalkanesulfonic acid anion such as CF₃S0₃₋, a pentafluorobenzenesulfonic acid anion, a condensed polynuclear aromatic sulfonic acid anion such as a naphthalene-1-sulfonic acid anion, an anthraquinonesulfonic acid anion and a sulfonic acid group-containing dye.

Two of R²⁰³, R²⁰⁴ and R²⁰⁵, and Ar₁ and Ar₂ may combine with each other through each single bond or substituent group.

Specific examples thereof include but are not limited to the following compounds:

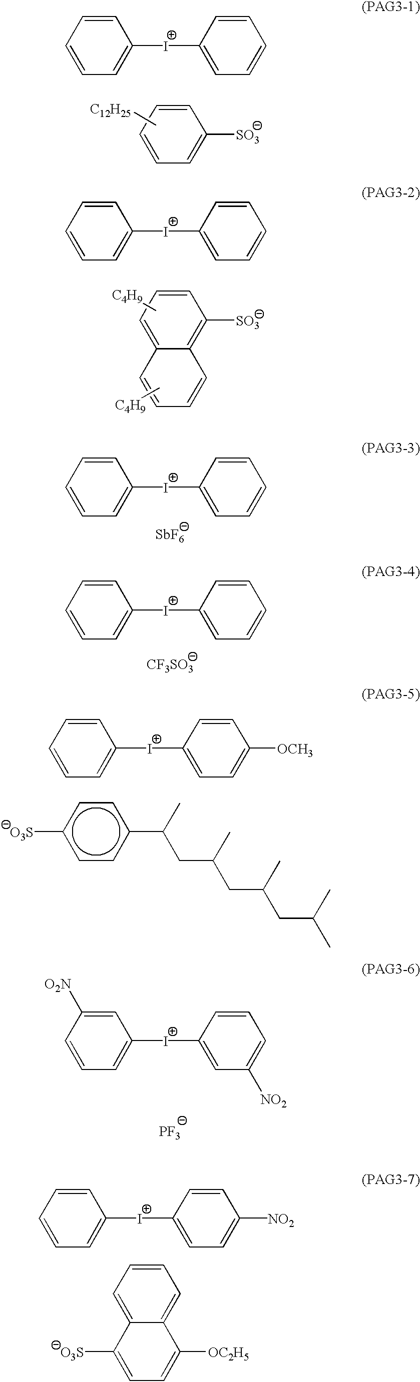

In the above, Ph represents a phenyl group.

The above-mentioned onium salts represented by general formulas (PAG3) and (PAG4) are known, and can be synthesized, for example, by methods described in U.S. Pat. Nos. 2,807,648 and 4,247,473, and Japanese Patent Laid-Open No. 101331/1978.

(3) Disulfone derivatives represented by the following general formula (PAG5) or iminosulfonate derivatives represented by the following general formula (PAG6):

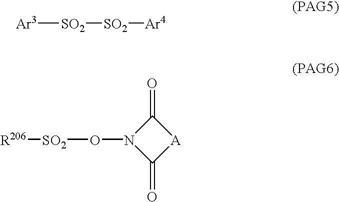

wherein Ar³ and Ar⁴ each independently represents an unsubstituted or substituted aryl group; R²⁰⁶ represents an unsubstituted or substituted alkyl or aryl group; and A represents an unsubstituted or substituted alkylene, alkenylene or arylene group.

Specific examples thereof include but are not limited to the following compounds:

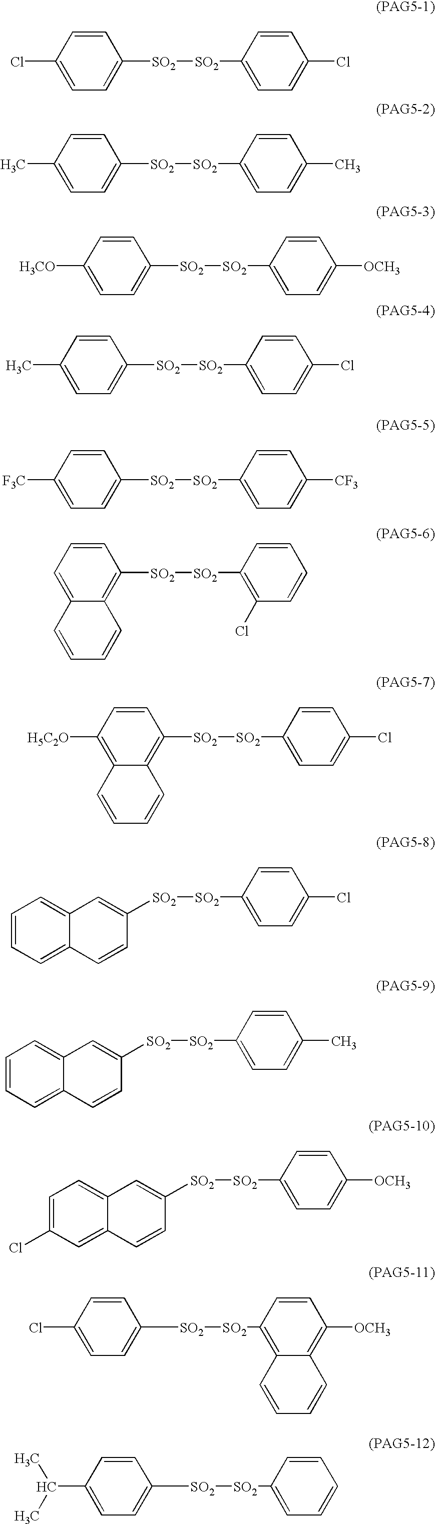

(4) Diazodisulfone derivatives represented by the following general formula (PAG7):

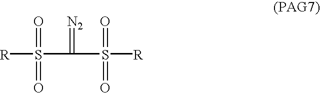

wherein R represents a straight-chain, branched or cyclic alkyl group, or an aryl group which may be substituted.

Specific examples thereof include but are not limited to the following compounds:

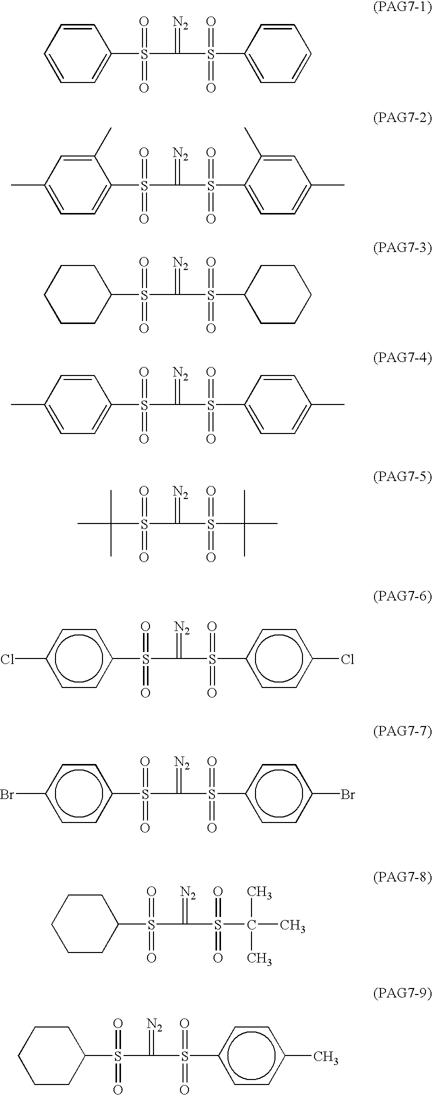

These photoacid generating agents are added usually in an amount of 0.01% to 30% by weight, preferably in an amount of 0.3% to 20% by weight, and more preferably in an amount of 0.5% to 10% by weight, based on the solid matter contained in the composition.

When the photoacid generating agents are added in an amount of less than 0.01% by weight, the sensitivity tends to decrease. On the other hand, when they are added in an amount of more than 30% by weight, the light absorption of the resists becomes too high, which tends to cause deterioration of profiles and narrowing of process (particularly, bake) margins.

[3] Other Additives

The positive resist composition of the invention may further contain a compound for preventing acid-decomposable dissolution, a dye, a plasticizer, a surfactant, a photosensitizer, an organic basic compound and a compounds for enhancing the solubility in a developing solution, as needed.

The positive resist composition of the invention preferably contains (C) a fluorine and/or silicone surfactant.

It is preferred that the positive resist composition of the invention contains any one of a fluorine surfactant, a silicone surfactant and a surfactant containing both a fluorine atom and a silicon atom, or two or more of them.

The positive resist composition of the invention contains the above-mentioned acid-decomposable resin and the above-mentioned surfactant, thereby further improving the development defects. This is particularly effective when the line width of patterns is thinner.

These surfactants include, for example, surfactants described in Japanese Patent Laid-Open Nos. 36663/1987, 226746/1986, 226745/1986, 170950/1987, 34540/1988, 230165/1995, 62834/1996, 54432/1997 and 5988/1997 and U.S. Pat. Nos. 5,405,720, 5,360,692, 5,529,881, 5,296,330, 5,436,098, 5,576,143, 5,294,511 and 5,824,451. The following commercially available surfactants can also be used as such.

The commercially available surfactants which can be used include, for example, fluorine surfactants or silicone surfactants such as Eftop EF301 and EF303 (manufactured by Shin Akita Kasei Co., Ltd.), Florard FC430 and FC431 (manufactured by Sumitom 3M Ltd.), Megafack F171, F173, F176, F189 and R08 (manufactured by Dainippon Ink & Chemicals Inc.), Surflon S-382, SC101, SC102, SC103, SC104, SC105 and SC106 (manufactured by Asahi Glass Co., Ltd.) and Tory Sol S-366 (manufactured by Troy Chemical Co., Ltd.). Further, Polysiloxane Polymer KP-341 (manufactured by Shin-Etsu Chemical Co., Ltd.) can also be used as a silicone surfactant.

The amount of the surfactant added is usually from 0.001% to 2% by weight, and preferably from 0.01% to 1% by weight, based on the solid matter in the composition of the invention. These surfactants may be added either alone or as a combination of some of them.

In addition to the above, specific examples of the surfactants which can be used include nonionic surfactants such as polyoxyethylene alkyl ethers such as polyoxyethylene lauryl ether, polyoxyethylene stearyl ether, polyoxyethylene cetyl ether and polyoxyethylene oleyl ether; polyoxyethylene alkyl allyl ethers such as polyoxyethylene octyl phenol ether and polyoxyethylene nonyl phenol ether; polyoxyethylene-polyoxypropylene block copolymers; sorbitan fatty acid esters such as sorbitan monolaurate, sorbitan monopalmitate, sorbitan monostearate, sorbitan monooleate, sorbitan trioleate and sorbitan tristearate; and polyoxyethylene sorbitan fatty acid esters such as polyoxyethylene sorbitan monolaurate, polyoxyethylene sorbitan monopalmitate, polyoxyethylene sorbitan monostearate, polyoxyethylene sorbitan trioleate and polyoxyethylene sorbitan tristearate.

The amount of these surfactants added is usually 2 parts by weight or less, and preferably 1 part by weight or less, per 100 parts by weight of the solid matter in the composition of the invention.

The organic basic compound (D) which can be preferably used in the invention is a compound stronger in basicity than phenol. Above all, a nitrogen-containing basic compound is preferred.

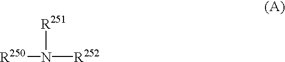

wherein R²⁵⁰,R²⁵¹ and R²⁵², which may be the same or different, each represents a hydrogen atom, an alkyl group having 1 to 6 carbon atoms, an aminoalkyl group having 1 to 6 carbon atoms, a hydroxyalkyl group having 1 to 6 carbon atoms, or an unsubstituted or substituted aryl group, wherein R²⁵¹ and R²⁵² may combine with each other to form a ring.

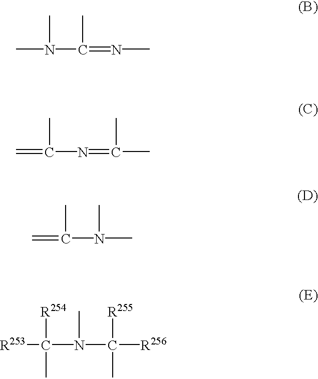

wherein R²⁵³,R²⁵⁴, R²⁵⁵ and R²⁵⁶, which may be the same or different, each represents an alkyl group having 1 to 6 carbon atoms.

More preferred is a nitrogen-containing basic compound having two or more nitrogen atoms different in chemical environment, and particularly preferred is a compound having both an unsubstituted or substituted amino group and a nitrogen atom-containing ring structure, or a compound having an alkylamino group. Preferred examples thereof include unsubstituted or substituted guanidine, unsubstituted or substituted arninopyridine, an unsubstituted or substituted aminoalkylpyridine, unsubstituted or substituted aminopyrrolidine, unsubstituted or substituted indazole, unsubstituted or substituted pyrazole, unsubstituted or substituted pyrazine, unsubstituted or substituted pyrimidine, unsubstituted or substituted purine, unsubstituted or substituted imidazoline, unsubstituted or substituted pyrazoline, unsubstituted or substituted piperazine, unsubstituted or substituted aminomorpholine and an unsubstituted or substituted aminoalkylmorpholine. Preferred substituent groups are an amino group, an aminoalkyl group, an alkylamino group, an aminoaryl group, an arylamino group, an alkyl group, an alkoxyl group, an acyl group, an acyloxy group, an aryl group, an aryloxy group, a nitro group, a hydroxyl group and a cyano group.

Preferred specific examples of the nitrogen-containing basic compounds include but are not limited to guanidine, 1,1-dimethylguanidine, 1,1,3,3-tetramethylguanidine, 2-aminopyridine, 3-aminopyridine, 4-aminopyridine, 2-dimethylaminopyridine, 4-dimethylaminopyridine, 2-diethylaminopyridine, 2-(aminomethyl)pyridine, 2-amino-3-methylpyridine, 2-amino-4-methylpyridine, 2-amino-5-methylpyridine, 2-amino-6-methylpyridine, 3-aminoethylpyridine, 4-aminoethylpyridine, 3-aminopyrrolidine, piperazine, N-(2-aminoethyl)piperazine, N-(2-aminoethyl)piperidine, 4-amino-2,2,6,6-tetramethylpiperidine, 4-piperidinopiperidine, 2-iminopiperidine, 1-(2-aminoethyl)pyrrolidine, pyrazole, 3-amino-5-methylpyrazole, 5-amino-3-methyl-1-p-tolylpyrazole, pyrazine, 2-(aminomethyl)-5-methylpyrazine, pyrimidine, 2,4-diaminopyrimidine, 4,6-dihydroxypyrimidine, 2-pyrazoline, 3-pyrazoline, N-aminomorpholine, N-(2-aminoethyl)morpholine, 1,5-diazabicyclo[4.3.0]nona-5-ene, 1,8-diazabicyclo [5.4.0]undeca-7-ene, 1,4-diazabicyclo[2.2.2]octane, 2,4,5-triphenylimidazole, N-methylmorpholine, N-ethylmorpholine, N-hydroxyethylmorpholine, N-benzylmorpholine, a tertiary morpholine derivative such as cyclohexylmorpholinoethylthiourea (CHMETU) and hindered amines described in Japanese Patent Laid-Open No. 52575/1999 (for example, ones described in paragraph number [0005]).

Particularly preferred specific examples thereof include 1,5-diazabicyclo[4.3.0]nona-5-ene, 1,8-diazabicyclo [5.4.0]undeca-7-ene, 1,4-diazabicyclo[2.2.2]octane, 4-dimethylaminopyridine, hexamethylenetetramine, 4,4-dimethylimidazoline, pyrrole and derivatives thereof, pyrazole and derivatives thereof, imidazole and a derivative thereof, pyridazine and a derivative thereof, pyrimidine and a derivative thereof, a tertiary morpholine derivative such as CHMETU, and a hindered amine such as bis(1,2,2,6,6-pentamethyl-4-piperidyl) sebacate.

Above all, preferred are 1,5-diazabicyclo[4.3.0]-nona-5-ene, 1,8-diazabicyclo[5.4.0]undeca-7-ene, 1,4-diazabicyclo[2.2.2]octane, 4-dimethylaminopyridine, hexamethylenetetramine, CHMETU and bis(1,2,2,6,6-pentamethyl-4-piperidyl) sebacate.

These nitrogen-containing basic compounds are used alone or as a combination of two or more of them. The amount of the nitrogen-containing basic compound used is usually from 0.001% to 10% by weight, and preferably form 0.01% to 5% by weight, based on the solid matter of the whole photosensitive resin composition. Less than 0.001% by weight does not give the effects of addition of the above-mentioned nitrogen-containing basic compound, whereas exceeding 10% by weight results in a tendency of the sensitivity to decrease and a tendency of the development properties of non-exposed areas to deteriorate.

The composition of the invention is dissolved in a solvent dissolving each component described above, and applied onto a support. As the solvents used herein, preferred are diethylene dichloride, cyclohexanone, cyclopentanone, 2-heptanone, γ-butyrolactone, methyl ethyl ketone, ethylene glycol monomethyl ether, ethylene glycol monoethyl ether, 2-methoxyethyl acetate, ethylene glycol monoethyl ether acetate, propylene glycol monomethyl ether, propylene glycol monomethyl ether acetate, toluene, ethyl acetate, butyl acetate, methyl lactate, ethyl lactate, methyl methoxypropionate, ethyl ethoxypropionate, methyl pyruvate, ethyl pyruvate, propyl pyruvate, N,N-dimethylformamide, dimethyl sulfoxide, N-methylpyrrolidinone and tetrahydrofuran. These solvents are used either alone or as a mixture thereof.

Of the above, preferred examples of the solvents include propylene glycol monomethyl ether acetate, 2-heptanone, γ-butyrolactone, ethylene glycol monomethyl ether, ethylene glycol monoethyl ether, ethylene glycol monoethyl ether acetate, propylene glycol monomethyl ether, propylene glycol monoethyl ether, butyl acetate, methyl lactate, ethyl lactate, methyl methoxypropionate, ethyl ethoxypropionate, N-methylpyrrolidinone and tetrahydrofuran.

Such a positive photoresist composition of the invention is applied onto a substrate to form a thin film. The thickness of the coating film is preferably from 0.2 to 1.2 μm.

Inorganic substrates which can be used in the invention include an ordinary bare Si substrate, an SOG substrate and a substrate having an inorganic antireflection film described below.

In the invention, a commercially available inorganic or organic antireflection film can be used as needed.

As the antireflection film, there can be used an inorganic film composed of titanium, titanium oxide, titanium nitride, chromium oxide, carbon or α-silicon, or an organic film composed of a light absorbing agent and a polymer material. The former requires equipment such as a vacuum deposition apparatus, a CVD apparatus or a sputtering apparatus. The organic antireflection films include, for example, a film comprising a condensate of a diphenylamine derivative and a formaldehyde-modified melamine resin, an alkali-soluble resin and a light absorbing agent, which is described in Japanese Patent Publication No. 69611/1995, a reaction product of a maleic anhydride copolymer and a diamine type light absorbing agent, which is described in U.S. Pat. No. 5,294,680, a film containing a resin binder and a methylolmelamine-based heat crosslinking agent, which is described in Japanese Patent Laid-Open No. 118631/1994, an acrylic resin type antireflection film having a carboxylic acid group, an epoxy group and a light absorbing group in the same molecule, which is described in Japanese Patent Laid-Open No. 118656/1994, a film comprising methylolmelamine and a benzophenone light absorbing agent, which is described in Japanese Patent Laid-Open No. 87115/1996, and a film comprising a polyvinyl alcohol resin and a low molecular weight light absorbing agent added thereto, which is described in Japanese Patent Laid-Open No. 179509/1996.

Further, as the organic antireflection films, there can also be used a DUV-30 series, a DUV-40 series and ARC25 manufactured by Brewer Science Co., and AC-2, AC-3, AR19 and AR20 manufactured by Sipray Co.

The above-mentioned resist solution is applied onto a substrate (for example, a silicon/silicon dioxide coating) as used for the production of a precision integrated circuit element (onto a substrate provided with the above-mentioned antireflection film as needed) by an appropriate coating method such as a method using a spinner or a coater, followed by exposure through a specified mask, baking and development. Thus, a good resist pattern can be obtained. Exposure light used herein is light having a wavelength of 150 nm to 250 nm. Specific examples thereof include a KrF excimer laser beam (240 nm)), an ArF excimer laser beam (193 nm), an F₂ excimer laser beam (157 nm), X-rays and electron beams.

Developing solutions include an alkaline aqueous solution of an inorganic alkali such as sodium hydroxide, potassium hydroxide, sodium carbonate, sodium silicate, sodium metasilicate or aqueous ammonia; a primary amine such as ethylamine or n-propylamine; a secondary amine such as z diethylamine or di-n-butylamine; a tertiary amine such as triethylamine or methyldiethylamine; an alcohol amine such as dimethylethanolamine or triethanolamine; a quaternary ammonium salt such as tetramethylammonium hydroxide or tetraethylammoniumhydroxide; or a cyclic amine such as pyrrole or piperidine.

Further, an alcohol and a surfactant can also be added in appropriate amounts to the above-mentioned alkaline aqueous solution.

### EXAMPLES

The invention will hereinafter be described with reference to examples in more detail below, but the following examples are not intended to limit the scope of the invention.

### Synthesis Example (1)

### Synthesis of Resin (1)

2-Methyl-2-adamantyl methacrylate, butyrolactone methacrylate, dimethylhydroxyadamantane methacrylate and dimethylhydroxyadamantane acrylate were placed in a reaction vessel at a molar ratio of 50/25/15/10, and dissolved in methyl ethyl ketone to prepare 100 ml of a solution having a solid content of 25%. To this solution, 8 mol % of a radical initiator (V-601, manufactured by Wako Pure Chemical Industries Ltd.) was added, and the resulting solution was added dropwise for 6 hours in a stream of nitrogen to 10 ml of methyl ethyl ketone heated at 75° C. After the dropping was completed, the reaction solution was heated for 2 hours. After the reaction was completed, the reaction solution was cooled to room temperature, and poured into 2 liters of a distilled water/isopropyl alcohol mixed solvent of 2/1 to precipitate a powder. The precipitated white powder, resin (1), was recovered.

The polymer composition ratio determined from C13 NMR was 51/25/16/8. Further, the weight average molecular weight determined by the GPC measurement was 10700 in terms of that of standard polystyrene.

Resins having composition ratios and molecular weights shown in Table 1 given below were synthesized in the same manner as with Synthesis Example (1). In Table 1, repeating units 1, 2, 3 and 4 is the order of structural formulas from the left.

TABLE 1

| | | | | | Amount of | | |
|---|---|---|---|---|---|---|---|
| | Repeating | Repeating | Repeating | Repeating | Acrylic | | |
| | Unit 1 | Unit 2 | Unit 3 | Unit 4 | Monomer | Molecular | |
| Resin | (mol %) | (mol %) | (mol %) | (mol %) | (mol %) | Weight | Remark |
| (1)-2 | 50 | 25 | 13 | 12 | 12 | 10600 | |
| (1)-3 | 50 | 25 | 5 | 20 | 20 | 11200 | |
| (1)-4 | 50 | 25 | 25 | 0 | 0 | 11100 | Compar- |
| | | | | | | | ison |
| (1)-5 | 50 | 25 | 22 | 3 | 3 | 10900 | Compar- |
| | | | | | | | ison |
| (2) | 39 | 21 | 10 | 30 | 30 | 11400 | |
| (3) | 42 | 22 | 10 | 26 | 26 | 10100 | |
| (4) | 40 | 18 | 6 | 36 | 36 | 10600 | |
| (5) | 50 | 17 | 20 | 13 | 13 | 9900 | |
| (6)-1 | 48 | 10 | 42 | — | 42 | 12100 | |
| (6)-2 | 48 | 2 | 50 | — | 50 | 10900 | Compar- |
| | | | | | | | ison |
| (7) | 35 | 40 | 25 | −28 | 25 | 12000 | |
| (8) | 45 | 16 | 11 | 18 | 28 | 11700 | |
| (9) | 50 | 6 | 26 | 11 | 18 | 10900 | |
| (10) | 42 | 30 | 17 | | 11 | 11300 | |

Structures of the above-mentioned resins (1) to (10) are shown below:

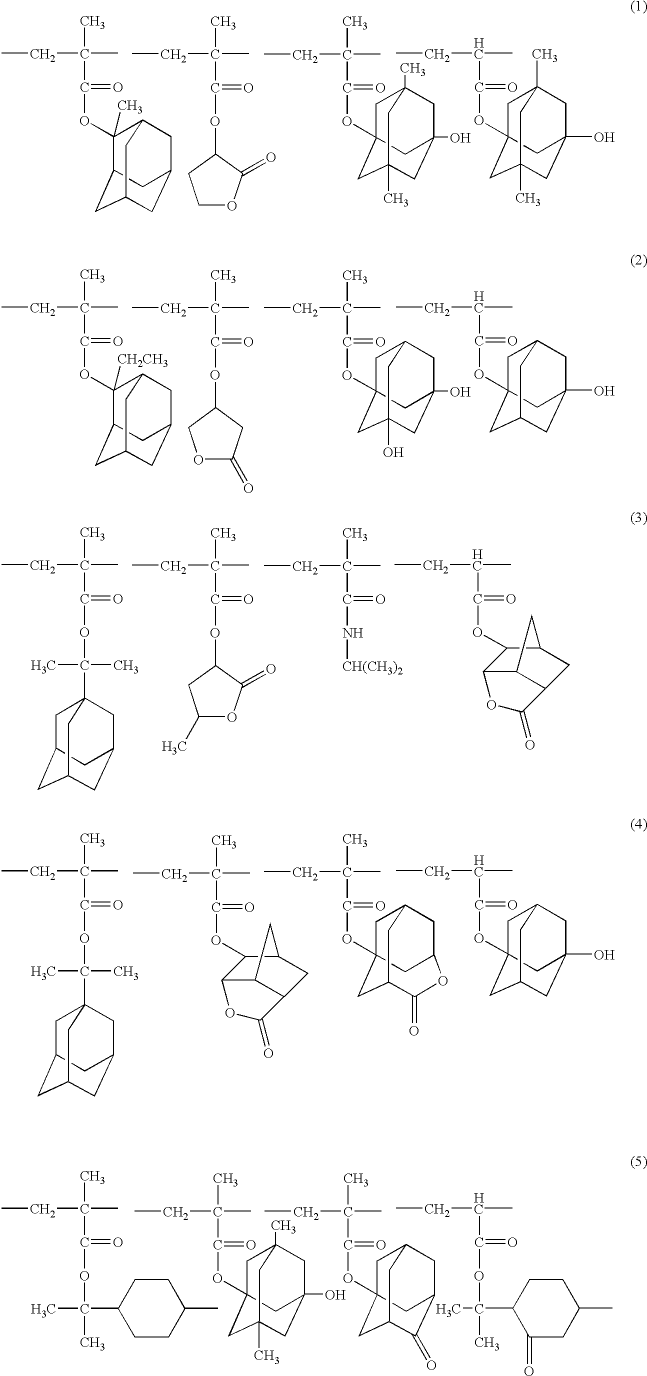

### Examples 1 to 12 and Comparative Examples 1 to 3

### Preparation and Evaluation of Positive Resist Compositions

The respective components shown in Table 2, which were prepared in the above-mentioned synthesis examples, were compounded, and each composition was dissolved in an ethyl lactate/butyl acetate mixed solvent of 60/40 in a solid content of 14% by weight. Then, each solution thus obtained was filtered through a 0.1-μm micro filter. Thus, positive resist compositions of Examples 1 to 12 and Comparative Examples 1 and 3 were prepared.

TABLE 2

| | | | Basic | |
|---|---|---|---|---|
| | Resin | Photoacid Gener- | Compound | Surfactant |
| | (10 g) | ating Agent | (15 mg) | (10 mg) |
| Example 1 | (1)-1 | PAG 4-48, 160 mg | 3 | W5 |
| Example 2 | (1)-2 | PAG 4-48/4-77, | 4 | W3 |
| | | 150/100 mg | | |
| Example 3 | (1)-3 | PAG 4-52, 180 mg | 5 | Not |
| | | | | added |
| Comparative | (1)-4 | PAG 4-48, 160 mg | 3 | Not |
| Example 1 | | | | added |
| Comparative | (1)-5 | PAG 4-48, 160 mg | 3 | W5 |
| Example 2 | | | | |
| Example 4 | (2) | PAG 4-50/4-53, | 4 | W1 |
| | | 80/200 mg | | |
| Example 5 | (3) | PAG 4-93, 420 mg | 1 | W1 |
| Example 6 | (4) | PAG 4-52/4-63, | 2 | W4 |
| | | 70/220 mg | | |
| Example 7 | (5) | PAG 4-39, 150 mg | 5 | W1 |
| Example 8 | (6)-1 | PAG 4-50, 185 mg | 4/5 = 1/1 | W5 |
| Comparative | (6)-2 | PAG 4-50, 185 mg | 4/5 = 1/1 | W5 |
| Example 3 | | | | |
| Example 9 | (7) | PAG 4-6/4-77, | 6 | W1 |
| | | 160/80 mg | | |
| Example 10 | (8) | PAG 4-17/4-37, | 5 | W2 |
| | | 100/25 mg | | |
| Example 11 | (9) | PAG 4-77/6-27, | 6 | W5 |
| | | 350/100 mg | | |
| Example 12 | (10) | PAG 4-36/4-24, | 3 | W5 |
| | | 140/30 mg | | |

As the surfactants,

W1 represents Megafack F176 (manufactured by Dainippon Ink & Chemicals Inc.) (fluorine surfactant);

W2 represents Megafack R08 (manufactured by Dainippon Ink & Chemicals Inc.) (fluorine and silicone surfactant);

W3 represents Polysiloxane Polymer KP-341 (manufactured by Shin-Etsu Chemical Co., Ltd.);

W4 represents polyoxyethylene nonyl phenyl ether; and

W5 represents Tory Sol S-366 (manufactured by Troy Chemical Co., Ltd.).

As the amines,

1 represents 1,5-diazabicyclo[4.3.0]-5-nonene (DBN);

2 represents bis(1,2,2,6,6-pentamethyl-4-piperidyl) sebacate;

3 represents tri-n-butylamine;

4 represents triphenylimidazole;

5 represents antipyrine; and

6 represents 2,6-diisopropylaniline.

First, ARC-25 manufactured by Brewer Science Co. was applied onto a silicon wafer with a spin coater to a thickness of 78 nm, and dried. Then, the positive photoresist composition solution obtained was applied thereon, and dried at 130° C. for 90 seconds to prepare a positive photoresist film having a thickness of about 0.4 μm, which was exposed with an ArF excimer laser (an ArF stepper manufactured by ISI Co., wavelength: 193 nm, NA: 0.6). After exposure, heat treatment was carried out at 120° C. for 90 seconds. Then, the photoresist film was developed with a 2.38-wt% aqueous solution of tetramethylammonium hydroxide, and rinsed with distilled water to obtain a resist pattern profile.

A resist pattern of the silicon wafer thus obtained was observed under a scanning microscope, and the resist was evaluated as described below.

Pattern Falling

For pattern falling, 0.13-μm and 0.12-μm patterns were observed in an exposure reproducing a line and space pattern (1/1) of 0.13 μm, and the line width at which the pattern began to fall down was measured. The smaller value shows that the resist is more excellent in pattern falling.

Surface Roughness in Etching

A 0.15-μm contact hole pattern was etched with CHF₃/0₂ plasma of 8/2 for 60 seconds, and a cross section and a surface of the resulting sample were observed under an SEM. One in which pin hole-like defects were developed (a lower layer of a site not to be processed was etched) was evaluated as “poor”, one in which although surface roughness was developed, no defects were developed with hole deformation observed was evaluated as “fair”, and good one in which surface roughness was little developed and no hole deformation was observed was evaluated as “good”.

Defocusing Latitude

As to defocusing latitude, the DOF (depth of focus) of a line and space pattern (1/1) of 0.13 μm was observed to measure the range satisfying a line width of 0.13 μm±10%.

Results of these evaluations are shown in Table 3.

TABLE 3

| | | Pattern | Surface | Defocusing |
|---|---|---|---|---|
| | | Falling | Roughness | Latitude |
| | Resin | (nm) | in Etching | (μm) |
| Example 1 | (1)-1 | 125 | Fair | 0.5 |
| Example 2 | (1)-2 | 122.5 | Good | 0.6 |
| Example 3 | (1)-3 | 125 | Good | 0.5 |
| Comparative | (1)-4 | 140 | Poor | 0.1 |
| Example 1 | | | | |
| Comparative | (1)-5 | 135 | Poor | 0.2 |
| Example 2 | | | | |
| Example 4 | (2) | 122.5 | Good | 0.6 |
| Example 5 | (3) | 120 | Good | 0.7 |
| Example 6 | (4) | 120 | Good | 0.7 |
| Example 7 | (5) | 120 | Good | 0.7 |
| Example 8 | (6)-1 | 120 | Good | 0.6 |
| Comparative | (6)-2 | 135 | Poor | 0.2 |
| Example 3 | | | | |
| Example 9 | (7) | 122.5 | Good | 0.6 |
| Example 10 | (8) | 120 | Good | 0.7 |
| Example 11 | (9) | 122.5 | Good | 0.6 |
| Example 12 | (10) | 122.5 | Good | 0.6 |

The results shown in Table 3 apparently reveal that the positive resist compositions of the invention are excellent in the prevention of pattern falling, surface roughness in etching and defocusing latitude.

The invention can provide the positive resist compositions excellent in the prevention of pattern falling, surface roughness in etching and defocusing latitude. Accordingly, the positive resist compositions of the invention can be suitably used for microphotofabrication using far ultraviolet rays, particularly ArF excimer laser beams.

This application is based on Japanese Patent application JP 2001-149862, filed May 18, 2001, the entire content of which is hereby incorporated by reference, the same as if set forth at length.

While the invention has been described in detail and with reference to specific examples thereof, it will be apparent to one skilled in the art that various changes andmodifications can be made therein without departing from the spirit and scope thereof.

What is claimed is:

1. A positive resist composition comprising the components of:
(A) a resin having an aliphatic cyclic hydrocarbon group on its side chain and being capable of increasing the solubility in an alkali developer by an action of acid; and
(B) a compound being capable of generating an acid by irradiation with one of an actinic light and radiation,
wherein the component (A) is a resin comprising at least one of repeating unit having a partial structure comprising an alicyclic hydrocarbon represented by one of the following general formulae (pI) to (pVI), and the content of the repeating units belonging to an acrylic monomer is from 5 to 45 mol % based on the total of the repeating units: 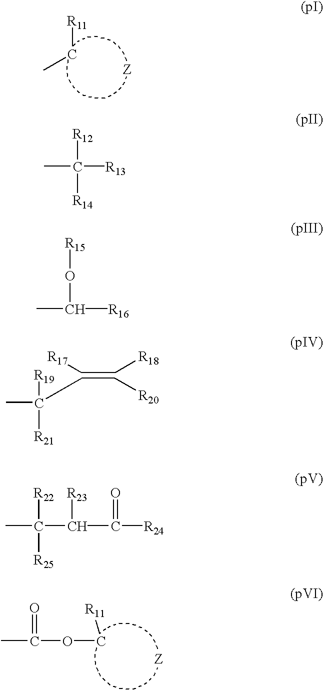
wherein R₁₁ represents a methyl group, an ethyl group, an n-propyl group, an isopropyl group, an n-butyl group, an isobutyl group or a sec-butyl group, and Z represents an atomic group necessary for forming an alicyclic hydrocarbon group together with a carbon atom; R₁₂ to R₁₆ each independently represents a straight-chain or branched alkyl group having from 1 to 4 carbon atoms or an alicyclic hydrocarbon group, with the proviso that at least one of R₁₂ to R₁₄, or either of R₁₅ and R₁₆ represents an alicyclic hydrocarbon group; R₁₇ to R₂₁ each independently represents a hydrogen atom, a straight-chain or branched alkyl group having from 1 to 4 carbon atoms or an alicyclic hydrocarbon group, with the proviso that at least one of R₁₇ to R₂₁ represents an alicyclic hydrocarbon group, and one of R₁₉ and R₂₁ represents a straight-chain or branched alkyl group having from 1 to 4 carbon atoms or an alicyclic hydrocarbon group; and R₂₂ to R₂₅ each independently represents a straight-chain or branched alkyl group having from 1 to 4 carbon atoms or an alicyclic hydrocarbon group, with the proviso that at least one of R₂₂ to R₂₅ represents an alicyclic hydrocarbon group, and R₂₃ and R₂₄ may combine with each other to form a ring.

2. The positive resist composition according to claim 1, wherein the content of the repeating units corresponding to an acrylic monomer is from 10 to 40 mol % based on the total of the repeating units.

3. The positive resist composition according to claim 1, wherein the content of the repeating units corresponding to an acrylic monomer is from 15 to 35 mol % based on the total of the repeating units.

4. The positive resist composition according to claim 1, which further comprises the component of: (C) a surfactant comprising at least one of a fluorine atom and a silicone atom.

5. The positive resist composition according to claim 1, which further comprises the component of: (D) an organic basic compound.

6. The positive resist composition according to claim 1, wherein the weight average molecular weight of the component (B) is from 1,000 to 200,000 as a value converted to that of polystyrene.

7. The positive resist composition according to claim 1, wherein the component (A) further comprises a repeating unit comprising a structure represented by the following formula (IV): 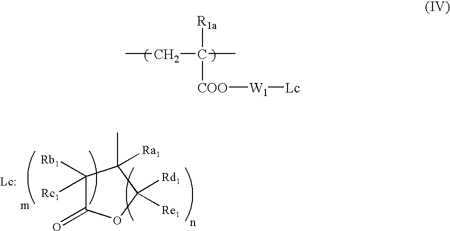
wherein R₁ₐ represents a hydrogen atom or a methyl group; W₁, represents a single bond or a combination of two or more groups selected from the group consisting of a single bond, an alkylene group, an ether group, a thioether group, a carbonyl group and an ester group; Ra₁, Rb₁, Rc₁, Rd₁ and Re₁ each independently represents a hydrogen atom or an alkyl group having from 1 to 4 carbon atoms; and m and n each independently represents an integer of from 0 to 3, provided that the sum of m and n is from 2 to 6.

8. The positive resist composition according to claim 1, wherein the component (A) further comprises a repeating unit comprising a structure represented by one of the following formulae (V-1), (V-2), (V-3) and (V-4): 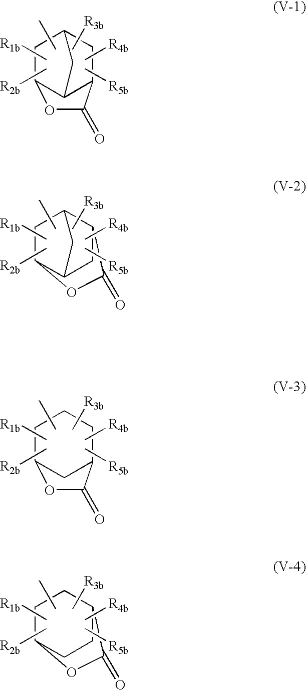
wherein R_{1b}, R_{2b}, R_{3b}, R_{4b} and R_{5b} each independently represents a hydrogen atom or an alkyl, cycloalkyl or alkenyl group which may have a substituent group; two of R_{1b}, R_{2b}, R_{3b}, R_{4b} and R_{5b} may combine with each other to form a ring.

9. The positive resist composition according to claim 1, wherein the component (A) further comprises a repeating unit comprising a structure represented by the following formula (VI): 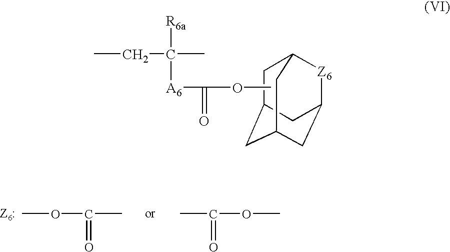
wherein A₆ represents a single bond or a combination of two or more groups selected from the group consisting of a single bond, an alkylene group, a cycloalkylene group, an ether group, a thioether group, a carbonyl group and an ester group; R₆ₐ represents a hydrogen atom, an alkyl group having from 1 to 4 carbon atoms, a cyano group or a halogen atom.

10. The positive resist composition according to claim 1, wherein the component (A) further comprises a repeating unit comprising a structure represented by the following formula (VII): 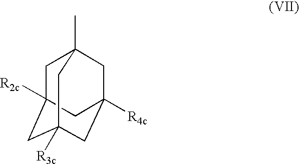
wherein R_{2c}, R_{3c} and R_{4c} each independently represents a hydrogen atom or a hydroxyl group, with the proviso that at least one of R_{2c}, R_{3c} and R_{4c} represents a hydroxyl group.

11. The positive resist composition according to claim 10, wherein at least two of R_{2c}, R_{3c} and R_{4c} represents a hydroxyl group.

12. The positive resist composition according to claim 1, wherein the component (A) further comprises a repeating unit comprising a structure represented by one of the following formulae (V-1), (V-2), (V-3) and (V-4): 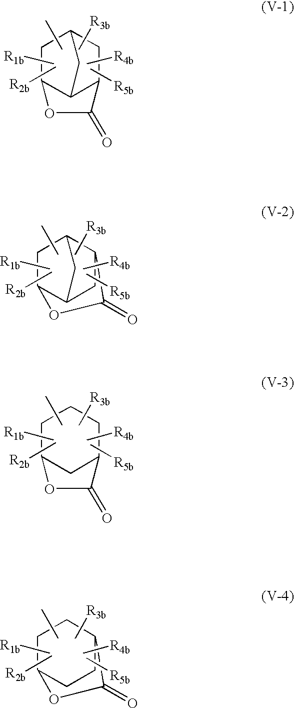
wherein R_{1b}, R_{2b}, R_{3b}, R_{4b} and R_{5b} each independently represents a hydrogen atom or an alkyl, cycloalkyl or alkenyl group which may have a substituent group; two of R_{1b}, R_{2b}, R_{3b}, R_{4b} and R_{5b} may combine with each other to form a ring,
and the component (A) further comprises a repeating unit comprising a structure represented by the following formula (VI): 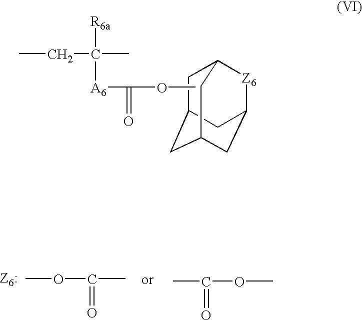
wherein A₆ represents a single bond or a combination of two or more groups selected from the group consisting of a single bond, an alkylene group, a cycloalkylene group, an ether group, a thioether group, a carbonyl group and an ester group; R₆ₐ, represents a hydrogen atom, an alkyl group having from 1 to 4 carbon atoms, a cyano group or a halogen atom.

13. The positive resist composition according to claim 1, wherein an amount of the component (B) is 0.001% to 30% by weight based on the solid content of the composition.

14. The positive resist composition according to claim 4, wherein an amount of the component (C) is 0.001% to 2% by weight based on the solid content of the composition.

15. The positive resist composition according to claim 7, wherein the component (D) is a compound having higher basicity than phenol.

16. The positive resist composition according to claim 7, wherein the component (D) is a nitrogen-containing basic compound.
